(19) United States
(12) Patent Application Publication
(10) Pub. No.: US 2007/0076371 A1
(43) Pub. Date: Apr. 5, 2007

(54) ELECTRONIC DEVICES WITH HEAT-DISSIPATION APPARATUSES

(75) Inventors: AN-PING CHOU, Tu-Cheng,Taipei Hsien (TW); HUANG-HUI LIAO, Tu-Cheng,Taipei Hsien (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,228

(22) Filed: Jul. 13, 2006

(30) Foreign Application Priority Data
Aug. 19, 2005 (CN) 200510036767.0

(51) Int. Cl. H05K 7/20

(52) U.S. Cl. 361/690

(57) ABSTRACT

An electronic device includes a frame (10) and a side blow fan (11). The frame includes a top portion (100), a bottom portion (120), and a plurality of side portions (130). The side portions connect with the bottom portion and the top portion. The bottom portion and at least one of the side portions define a plurality of apertures (126 and 136) respectively. The side blow fan is arranged in the top portion. The electronic device has a good effect of heat-dissipation, and can operate with fewer fans than conventional electronic devices to meet the requirements of heat-dissipation.

### FIELD OF THE INVENTION

The invention relates to electronic devices, and particularly to an electronic device with a heat-dissipation apparatus.

### DESCRIPTION OF RELATED ART

Over the past decades, there has been considerable growth in electronic technology. With the development of electronic technology, numerous modern electronic components, such as multifunctional chips, received in an electronic device can operate at high speeds, resulting in large amounts of heat. The heat must be efficiently dissipated in order to obtain an effective performance of the electronic components.

FIG. 5 illustrates air current flowing in a conventional electronic device assembly. The electronic device assembly comprises two frames 50 arranged in a cabinet (not shown) in a stack. Each of the frames 50 comprises a bottom portion 520 and a top portion 500. The bottom portion 520 defines a plurality of input apertures 526 for air intake to the frame 50, while the top portion 500 defines a plurality of output apertures 536 for venting. A plurality of cooling fans 60 is provided in the electronic device assembly for driving the air to dissipate heat generated by electronic components in the frames 50. The cooling fans 60 are each arranged in one of the bottom portions 520 of each of the frames 50.

During use, the cooling fans 60 intake air via the input apertures 526. The air flows up through the electronic components in the frames 50, to take away the heat generated by the electronic components, and flows out the output apertures 536 defined in the top portion 500. However, because of the stacked configuration of the frames 50, vented air from one frame 50 is drawn through the intake of the next frame 50. When this happens, the efficiency of the heat-dissipation of the electronic device assembly is degraded.

Therefore, a heretofore unaddressed need exists in the industry to overcome the aforementioned deficiencies and inadequacies.

### SUMMARY OF THE INVENTION

An aspect of the invention provides an electronic device. The electronic device comprises a frame and at least one side blow fan. The frame comprises a bottom portion, a top portion, and a plurality of side portions. The side portions connect with the bottom portion and the top portion. The bottom portion and at least one of the side portions define a plurality of apertures respectively. The at least one side blow fan is arranged in the top portion. Whereby the at least one side blow fan draws air into the frame via the apertures of the bottom portion, to take away heat generated by heat-generating components received in the frame, thereafter, the air is vented by the at least on side blow fan through the apertures of the side portions along a radial direction of the side blow fan.

Another aspect of the invention provides an electronic device assembly. The electronic device assembly comprises a plurality of frames and a plurality of side blow fans. Each of the frames comprises a bottom portion, a top portion, and a plurality of side portions. The side portions connect with the bottom portion and the top portion, the bottom portion and at least one of the side portions define a plurality of apertures respectively. The plurality of side blow fans is arranged in the top portion of each frame. Whereby the plurality of side blow fans draws air into each of the frames via the apertures of the bottom portion, and the air flows up through electronic components received in each of the frames to take away heat generated by the electronic components, thereafter, the air is directed by the side blow fans into the top portion along an axial direction of the side blow fans, and vented out via the apertures of the side portions along a radial direction of the side blow fans.

Other advantages and novel features will become more apparent from the following detailed description of preferred embodiments when taken in conjunction with the accompanying drawings, in which:

### BRIEF DESCRIPTION OF THE DRAWINGS

FIG. 1 is an exploded, isometric view of a frame of an electronic device in accordance with an exemplary embodiment of the present invention, the frame includes two side blow fans;

FIG. 2 is an enlarged, inverted, isometric view of one of the side blow fans of FIG. 1;

FIG. 3 is an assembled view of an electronic device assembly including two frames like that of FIG. 1;

FIG. 4 is a schematic diagram of air current flowing in the electronic device assembly of FIG. 3; and

FIG. 5 is a schematic diagram of air current flowing in a conventional electronic device assembly.

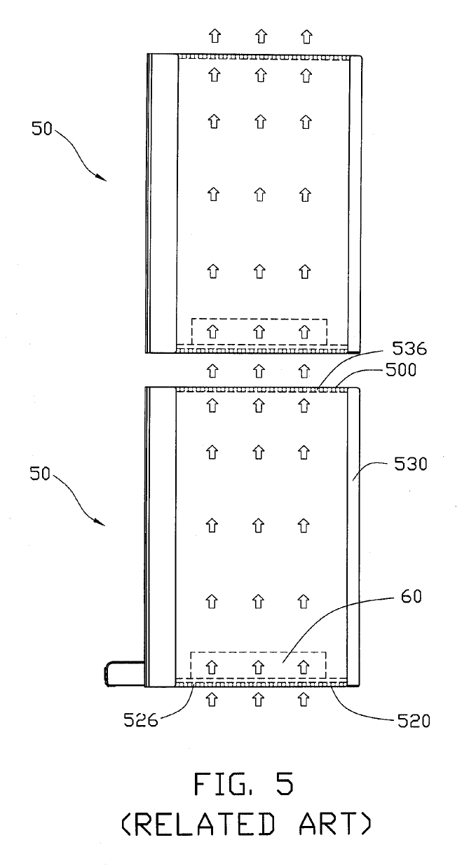

### DETAILED DESCRIPTION OF THE INVENTION

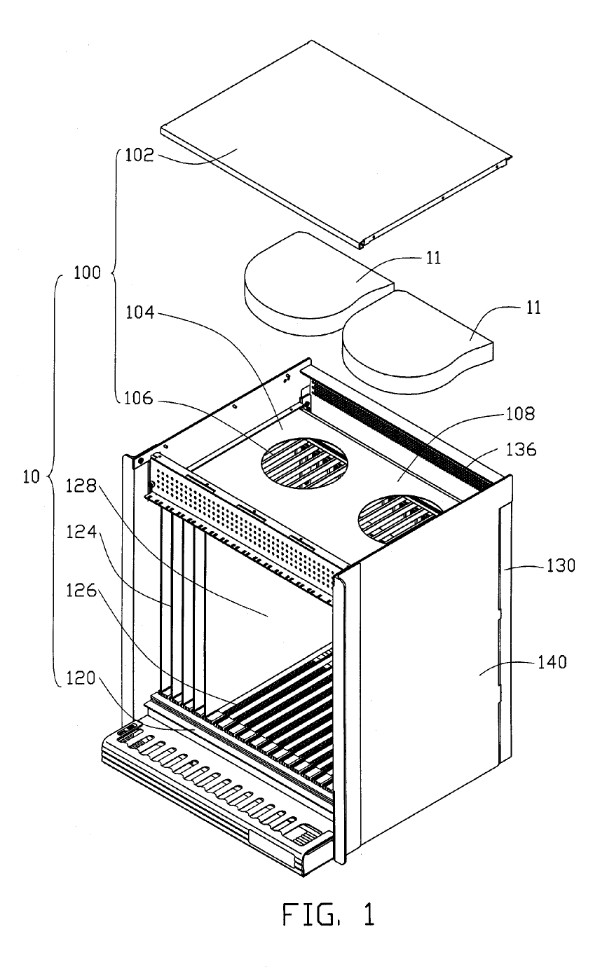

Referring to FIG. 1, a frame 10 of an electronic device in accordance with an exemplary embodiment of the present invention comprises two air-flow drivers like two side blow fans 11.

The frame 10 comprises a top portion 100, a bottom portion 120, and a plurality of side portions 130. The top portion 100 comprises an upper cover 102 and a lower cover 104, and defines a receiving portion 108 between the upper cover 102 and the lower cover 104. The side blow fans 11 are received in the receiving portion 108. The lower cover 104 defines two holes 106. The bottom portion 120 defines a plurality of input apertures 126 for intake of air into the frame 10. At least one of the side portions 130 defines a plurality of output apertures 136 adjacent to the top portion 100 for venting air. The side blow fans 11 are arranged on the lower cover 104 of the top portion 100, corresponding to the holes 106 in the lower cover 104. The lower cover 104, the side portions 130, and the bottom portion 120 cooperatively form a receiving space 128. The electronic device further comprises a plurality of electronic components 124 received in the receiving space 128 of the frame 10.

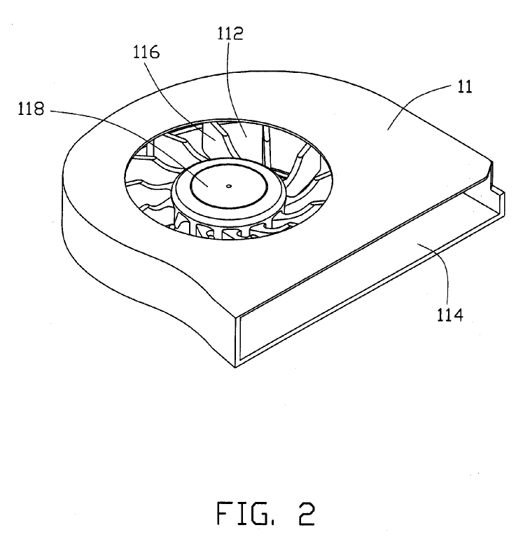

Referring to FIG. 2, each side blow fan 11 comprises a shaft 118, a plurality of fan blades 116, an inlet 112, and an outlet 114 communicating with the inlet 112. The inlet 112 allows air to be drawn into the side blow fan 10, and then vented through the outlet 114. A diameter of each of the inlets 112 is generally equal to that of the corresponding hole 106 in the lower cover 104. The fan blades 116 are arranged around the shaft 118. The shaft 118 is vertical to the upper cover 102 and the lower cover 104. Each inlet 112 is aligned with the corresponding one of the holes 106 of the lower cover 104, while the outlets 114 are aligned with the output apertures 136 of the side portion 130. Accordingly, air is drawn into the side blow fan 11 through the inlet 112 along an axial direction of the side blow fan 11, and then vented out through the outlet 114 along a radial direction of the side blow fan 11, through the output apertures 136 of the side portion 130. In the exemplary embodiment, the side blow fans 11 are centrifugal fans.

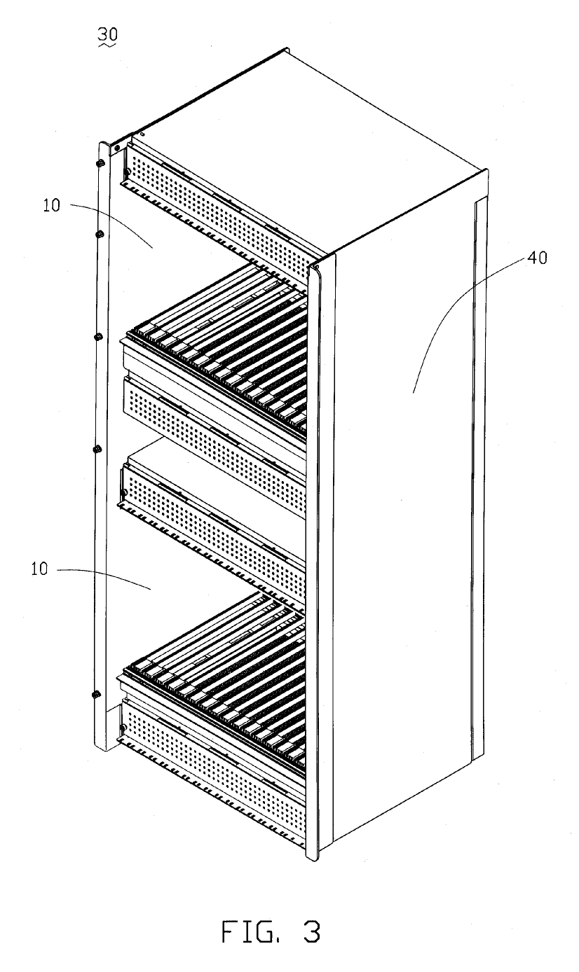

Referring to FIG. 3, it illustrates an electronic device assembly 30. The electronic device assembly 30 comprises two frames 10 stacked in a cabinet 40. Two side blow fans 11 are disposed in the top portion 100 of each of the frames 10.

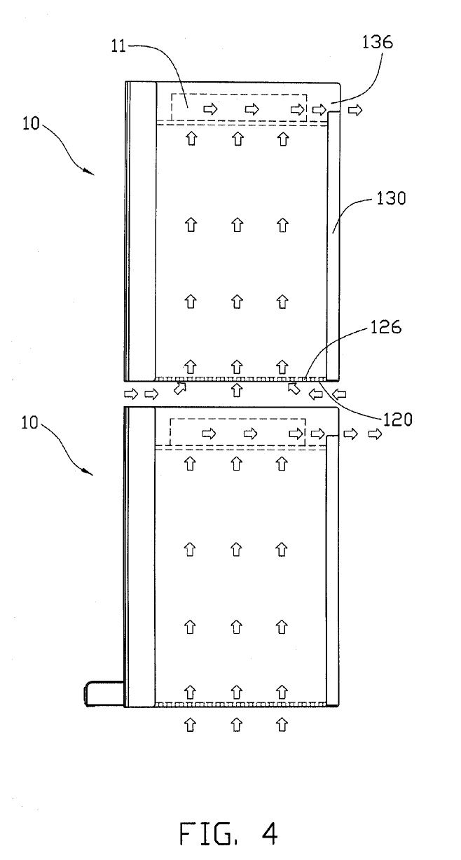

Referring to FIG. 4, a schematic diagram of air current flowing in the electronic device assembly 30 is shown. During use, air is drawn into each of the frames 10 along a first direction via the input apertures 126 of the bottom portions 120 by the side blow fans 11, to flow up through the electronic components 124 thus taking away heat generated by the electronic components in the frames 10, and being vented out via the output apertures 136 of the side portion 130 along a second direction perpendicular to the first direction.

With the output apertures 136 being defined in the side portions 130, the side blow fans 11 vent heated air away from adjacent frames 10. Therefore the frame 10 in the upper position of the cabinet 40 has a good effect of heat-dissipation.

While exemplary embodiment has been described above, it should be understood that it has been presented by way of example only and not by way of limitation. Thus the breadth and scope of the present invention should not be limited by the above-described exemplary embodiment, but should be defined only in accordance with the following claims and their equivalents.

What is claimed is:

1. An electronic device, comprising:
a frame comprising a bottom portion, a top portion, and a plurality of side portions, the side portions connecting with the bottom portion and the top portion, the bottom portion and at least one of the side portions defining a plurality of apertures respectively; and at least one side blow fan arranged in the top portion;
whereby the at least one side blow fan draws air into the frame via the apertures of the bottom portion, to take away heat generated by heat-generating components received in the frame, thereafter, the air is vented by the at least on side blow fan through the apertures of the side portions along a radial direction of the side blow fan.

2. The electronic device as claimed in claim 1, wherein the top portion comprises an upper cover and a lower cover.

3. The electronic device as claimed in claim 2, wherein the top portion defines a receiving portion between the upper cover and the lower cover.

4. The electronic device as claimed in claim 3, wherein the at least one side blow fan is received in the receiving portion.

5. The electronic device as claimed in claim 4, wherein the lower cover defines at least one hole corresponding to each of the at least one side blow fan.

6. The electronic device as claimed in claim 5, wherein the side blow fans comprise an inlet corresponding to the hole of the lower cover, and an outlet corresponding to the apertures of the side portions, the outlet communicating with the inlet.

7. The electronic device as claimed in claim 6, wherein the at least one side blow fan further comprises a shaft and a plurality of fan blades arranged around the shaft, the shaft is vertical to the lower cover and the upper cover.

8. An electronic device assembly, comprising:
a plurality of frames, each frame comprising a bottom portion, a top portion, and a plurality of side portions, the side portions connecting with the bottom portion and the top portion, the bottom portion, and at least one of the side portions defining a plurality of apertures respectively; and
a plurality of side blow fans arranged in the top portion of each of the frames;
whereby the plurality of side blow fans draw air into each of the frames via the apertures of the bottom portion, and the air flows up through electronic components received in each of the frames to take away heat generated by the electronic components, thereafter, the air is directed by the side blow fans into the top portion along an axial direction of the side blow fans, and vented out via the apertures of the side portions along a radial direction of the side blow fans.

9. The electronic device assembly as claimed in claim 9, wherein the top portion of each frame comprises an upper cover and a lower cover.

10. The electronic device assembly as claimed in claim 10, wherein the top portion of each frame defines a receiving portion between the upper cover and the lower cover.

11. The electronic device assembly as claimed in claim 11, wherein the side blow fans are received in the receiving portion of each frame.

12. The electronic device assembly as claimed in claim 12, wherein the lower cover defines at least one hole corresponding to each of the side blow fans.

13. The electronic device assembly as claimed in claim 13, wherein the side blow fans each comprise an inlet corresponding to the at least one hole of the lower cover, and an outlet corresponding to the apertures of the side portions.

14. The electronic device assembly as claimed in claim 9, wherein each side blow fan further comprises a shaft and a plurality of fan blades arranged around the shaft, the shaft is vertical to the lower cover and the upper cover.

15. An electronic device comprising:
a frame enclosing said electronic device comprising a first portion extending along a first side of said frame and a second portion extending along a second side of said frame opposite to said first side, said first portion comprising a plurality of input apertures formed along a first preset surface parallel to said first side of said frame to allow outside air flowing into said frame, and said second portion comprising a plurality of output apertures formed along a second preset surface perpendicular to said second side of said frame to allow air inside said frame flowing out of said frame;
a plurality of heat generating components removably installable in said frame between said first and second portions thereof, each of said plurality of components heat-communicable with said air inside said frame flowing around said each of said plurality of components; and
at least one air-flow driver enabling air flows in said frame from said first portion thereof toward said second portion thereof to urge said outside air flowing into said frame, and to expel said air inside said frame out of said frame.

16. The electronic device as claimed in claim 15, further comprising another electronic device structured same as said electronic device and installed next to said electronic device as a whole in a way that another first portion of said another electronic device closely neighbors and faces said second portion of said electronic device, and a plurality of another input apertures spread in said another first portion of said another electronic device along a third preset surface parallel to said second side of said frame of said electronic device for allow entry of said outside air into said another electronic device rather than said expelled air from said frame of said electronic device.

17. The electronic device as claimed in claim 15, wherein said second portion comprises a plurality of holes formed along a fourth preset surface parallel to said second side of said frame to allow said air inside said frame flowing into said second portion, and said at least one air-flow driver is installed in said second portion to be air communicable with said plurality of holes and said plurality of output apertures respectively.
